(19) United States
(12) Patent Application Publication
(10) Pub. No.: US 2008/0057657 A1
(43) Pub. Date: Mar. 6, 2008

(54) Method for fabrication of semiconductor device

(76) Inventor: YONG HO OH, Incheon (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/849,083

(22) Filed: Aug. 31, 2007

(30) Foreign Application Priority Data
Aug. 31, 2006 (KR) 10-2006-0083915

(51) Int. Cl. H01L 21/336

(52) U.S. Cl. 438/305; 257/E21.409

(57) ABSTRACT

A method of fabricating a semiconductor device is provided. The method includes: stacking a gate insulation layer and a polysilicon layer on a semiconductor substrate; forming a photoresist layer on the polysilicon layer; forming a gate stack by etching the gate insulation layer and the polysilicon layer; performing a first impurity ion implantation process to form a shallow first impurity area in the semiconductor substrate; forming a gate spacer layer on one side of the gate stack; and performing a second impurity ion implantation process to form a deep second impurity area in the semiconductor substrate.

### CROSS-REFERENCE TO RELATED APPLICATION

The present application claims the benefit under 35 U.S.C. §119 of Korean Patent Application No. 10-2006-0083915, filed Aug. 31, 2006, which is hereby incorporated by reference in its entirety.

### BACKGROUND

When fabricating a semiconductor device, a polysilicon layer is typically used as an electrode through a deposition process and an ion implantation process. During an ion implantation process, a doped polysilicon layer is often formed by implanting ions on deposited undoped polysilicon.

After an ion implantation process is performed, a post-thermal process is often required to maximize grain size and reduce sheet resistance. However, the post-thermal process generally makes boron (B) ions diffuse toward a gate electrode when forming a p+ polysilicon gate.

Boron ions around a gate oxide layer interface provide a depth profile distribution less than what is needed in a polysilicon layer. This leads to a degradation of the electrical characteristics of a semiconductor device due to poly-depletion.

Additionally, the post-thermal process often causes B ions to penetrate into the gate oxidation layer of a semiconductor device, thereby further deteriorating the electrical characteristics of the device.

Moreover, gate depletion limits the performance of a transistor when a gate structure is formed using polysilicon.

Thus, there exists a need in the art for an improved method of fabricating a semiconductor device.

### BRIEF SUMMARY

Embodiments of the present invention provide an improved method for fabricating a semiconductor device.

In an embodiment, a gate insulation layer and a polysilicon layer can be stacked on a semiconductor substrate, and a photoresist layer can be formed on the polysilicon layer. A gate stack can be formed by etching the gate insulation layer and the polysilicon layer. A first impurity ion implantation process can be performed to form a shallow first impurity area in the semiconductor substrate. A gate spacer layer can be formed on sides of the gate stack, and a second impurity ion implantation process can be performed using the gate spacer layer as a mask to form a deep second impurity area in the semiconductor substrate. The impurity ions that are implanted can be, for example, n-type impurity ions or p-type impurity ions.

According to the methods of fabricating semiconductor devices according to embodiments of the present invention, the effect of depletion of a polysilicon gate structure can be minimized, thereby improving a field effect transistor.

The details of one or more embodiments are set forth in the accompanying drawings and the detailed description below. Other features will be apparent to those skilled in the art from the detailed description, the drawings, and the appended claims.

### BRIEF DESCRIPTION OF THE DRAWINGS

FIGS. 1 through 3 are cross-sectional views illustrating a method for fabricating an NMOS transistor in a semiconductor device according to an embodiment of the present invention.

FIGS. 4 through 6 are cross-sectional views illustrating a method for fabricating a PMOS transistor in a semiconductor device according to an embodiment of the present invention.

FIGS. 7 and 8 are pictures showing results of implanting impurity ions according to the related art.

FIGS. 9 and 10 are pictures showing results of implanting impurity ion according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Embodiments of the present invention include methods for forming an n-channel metal oxide semiconductor (NMOS) transistor as well as a p-channel metal oxide semiconductor (PMOS) transistor.

Additionally, embodiments of the present invention include a method of fabricating a complementary metal oxide semiconductor field effect transistor (CMOSFET) device using an ion implantation process.

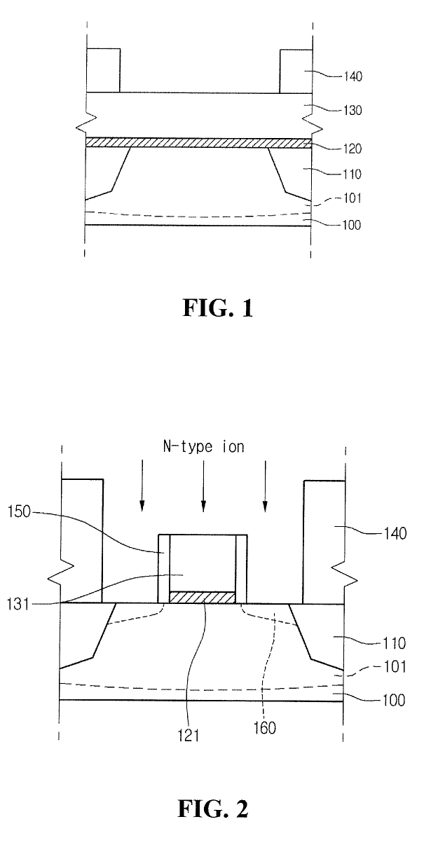

Referring to FIG. 1, in an embodiment, a p-type well 101 with implanted p-type impurity ions can be formed on an n-type semiconductor substrate 100.

A device isolation layer 110 can be formed on the semiconductor substrate 100 to define an active area where a transistor may be formed. The device isolation layer 110 can be formed by, for example, a shallow trench isolation (STI) process.

Then, a first gate insulation layer 120 can be formed on the semiconductor substrate, and a polysilicon layer 130 can be formed on the first gate insulation layer 120.

A photoresist layer 140 can be formed on the polysilicon layer 130 to perform an ion implantation process for an NMOSFET separately from a PMOSFET.

Referring to FIG. 2, after implanting ions into the polysilicon layer 130, the first gate insulation layer 120 and the polysilicon layer 130 can be etched to form a gate stack including a second gate insulation layer 121 and a gate conductive layer 131.

Optionally, a first gate spacer layer 150 can be formed at the side wall of the gate stack. For example, the first gate spacer layer 150 can be a tetra ethyl oxysilane (TEOS) layer with a thickness of from about 100 Å to about 300 Å.

Then, n-type impurity ions can be implanted on the entire surface of the semiconductor substrate 100 using the photoresist layer 140 as a mask in a first n-type ion implantation process.

In an embodiment, the n-type impurity ions can be arsenic (As). For example, from about 1.5×10¹⁵ atoms/cm² to about 2.5×10¹⁵ atoms/cm² of arsenic (As) can be implanted with an implantion energy of about 25 keV to about 35 keV.

In a further embodiment, phosphorus (P) can be implanted with arsenic (As) as the n-type impurity ions. For example, arsenic (As) and phosphorus (P) can be implanted at a ratio of about 2:1 (As:P). Phosphorus (P) can be implanted with an implantation energy of about 8 keV.

Accordingly, the first n-type impurity ion implantation process can form a thin shallow first impurity area 160.

Referring to FIG. 3, a second gate spacer layer 180 can be formed at a side of the gate conductive layer 131. A second n-type impurity ion implantation process can be performed using the second gate spacer layer 180 as a mask to form a high density deep second impurity area 170.

In an embodiment, As can be used as the n-type impurity ions for the second n-type impurity ion implantation process. For example, As ions can be implanted with an implantation energy of from about 25 keV to about 35 keV.

In a further embodiment, a diffusion process can be performed to diffuse the implanted impurity ions. For example, a diffusion process can be performed as a rapid thermal process at a temperature of about 700° C. to about 1050° C. in a nitrogen (N₂) atmosphere for a period of time of about 5 seconds to about 30 seconds.

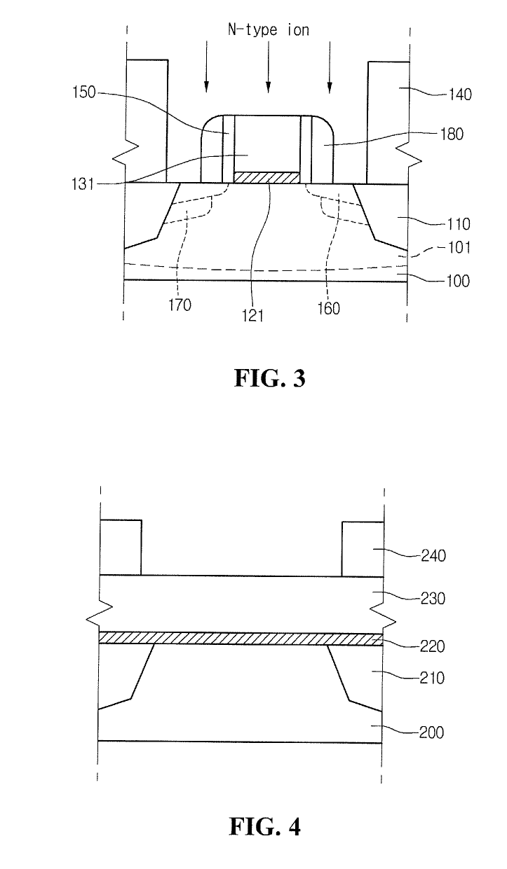

FIGS. 4 through 6 are cross-sectional views illustrating a method for fabricating a PMOS transistor in a semiconductor device according to an embodiment of the present invention.

Referring to FIG. 4, in an embodiment, a device isolation layer 210 can be formed on an n-type semiconductor substrate 200 to define an active area where a transistor may be formed. The device isolation layer 210 can be a trench-type device isolation layer.

Then, a first gate insulation layer 220 can be formed on the semiconductor substrate 200, and a polysilicon layer 230 can be formed on the first gate insulation layer 220.

A photoresist layer 240 can be formed on the polysilicon layer 230 to perform an ion implantation process for the polysilicon layer 230 separately from the adjacent NMOSFET.

Referring to FIG. 5, the first gate insulation layer 220 and the polysilicon layer 230 can be etched to form a gate stack including a second gate insulation layer 221 and a gate conductive layer 231.

Optionally, a first gate spacer layer 250 can be formed at the side wall of the gate stack. For example, the first gate spacer layer 250 can be a TEOS layer with a thickness of from about 100 Å to about 300 Å.

Then, a first p-type impurity ion implantation process can be performed on the entire surface of the semiconductor substrate 200 to form a low density shallow first impurity area 260. In an embodiment, the first p-type impurity ion implantation process can include mixing and implanting boron (B) ions and BF₃ ions.

Referring to FIG. 6, a second gate spacer layer 280 can be formed at one side of the gate conductive layer 231. A second p-type impurity ion implantation process can be performed using the second spacer layer 280 as a mask to form a deep second impurity area 270.

The second p-type impurity ion implantation process can implant ions at an implantation energy of from about 10 keV to about 20 keV.

In an embodiment, a diffusion process can be performed to diffuse the implanted impurity ions. For example, a diffusion process can be performed as a rapid thermal process at a temperature of about 700° C. to about 1050° C. in an N₂ atmosphere for a period of time of about 5 second to about 30 seconds.

Table 1 compares characteristics of NMOS devices of the related art to those according to an embodiment of the present invention. Table 2 compares characteristics of PMOS devices of the related art to those according to an embodiment of the present invention.

Tables 1 and 2 show that the influence of depletion in the polysilicon layer is reduced by the impurity ion implantation process of embodiments of the present invention. For example, on/off currents are lower in devices according to embodiments of the present invention compared to those of the related art.

TABLE 1
Threshold voltage and on/off currents of NMOS devices

| NMOS | Related art | Present invention |
|---|---|---|
| Vₜₕᵢ(V) | 0.243 | 0.316 |
| Iₒₙ(μA/μm) | 645 | 549 |
| I_{off}(A/μm) | 5.20E−08 | 2.03E−09 |

TABLE 2
Threshold voltage and on/off currents of PMOS devices

| PMOS | Related art | Present Invention |
|---|---|---|
| Vₜₕᵢ(V) | −0.204 | −0.235 |
| Iₒₙ(μA/μm) | 345 | 330 |
| I_{off}(A/μm) | 3.1E−07 | 1.21E−07 |

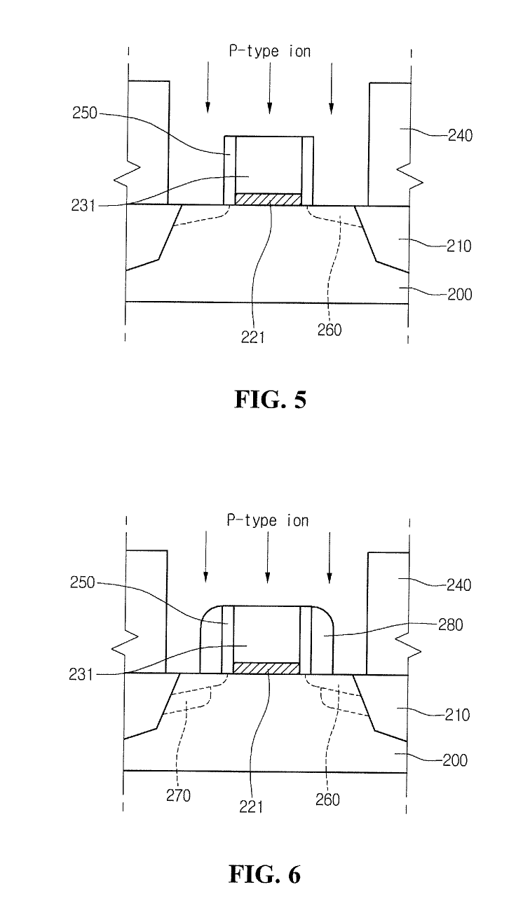

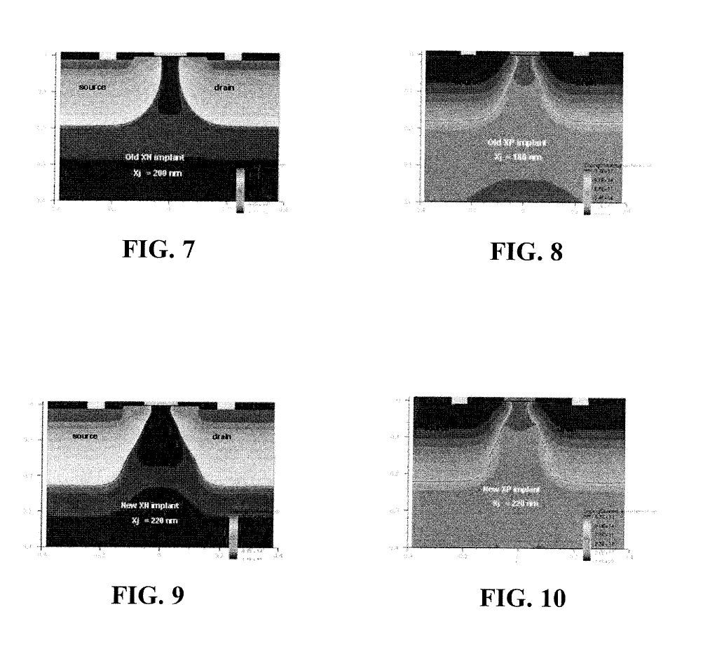

FIGS. 7 and 8 show results of implanting impurity ions according to the related art, while FIGS. 9 and 10 show results of implanting impurity ions according to an embodiment of the present invention.

Referring to FIGS. 7 and 8, in the related art, a shallow impurity area is formed very close to a deep impurity area at a source and drain area of a semiconductor substrate.

However, referring to FIGS. 9 and 10, in an embodiment of the present invention, a shallow impurity area is separated from a deep impurity area in a source and drain area of a semiconductor substrate. Accordingly, the on/off characteristics of the semiconductor device are improved and gate depletion is inhibited.

Methods for fabricating a semiconductor device according to embodiments of the present invention can provide an improved field effect transistor, which is often degraded in the related art due to the polysilicon gate structure.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, comprising:
forming a gate insulation layer on a semiconductor substrate;
forming a polysilicon layer on the gate isolation layer;
etching the gate insulation layer and the polysilicon layer to form a gate stack;
performing a first n-type impurity ion implantation process to form a shallow first impurity area in the semiconductor substrate;
forming a gate spacer layer on one side of the gate stack; and
performing a second n-type impurity ion implantation process using the gate spacer layer as a mask to form a deep second impurity area in the semiconductor substrate.

2. The method according to claim 1, wherein the performing a first n-type impurity ion implantation process comprises implanting arsenic (As) ions.

3. The method according to claim 2, wherein the As ions are implanted at an implantation energy in the range of from about 25 keV to about 35 keV.

4. The method according to claim 2, wherein the performing a first n-type impurity ion implantation process further comprises implanting phosphorous (P) ions, and wherein the As ions and P ions are implanted at a ratio of about 2:1 (As:P).

5. The method according to claim 4, wherein the P ions are implanted at an implantation energy of about 8 keV.

6. The method according to claim 1, wherein the performing a second n-type impurity ion implantation process comprises implanting arsenic (As) ions.

7. The method according to claim 6, wherein the As ions are implanted at an implantation energy in the range of from about 10 keV to about 20 keV.

8. The method according to claim 6, wherein the performing a second n-type impurity ion implantation process further comprises implanting phosphorous (P) ions, and wherein the As ions and P ions are implanted at a ratio of about 2:1 (As:P).

9. The method according to claim 1, further comprising performing a diffusion process to diffuse the implanted impurity ions.

10. The method according to claim 9, wherein the diffusion process is a rapid thermal process performed at a temperature of from about 700° C. to about 1050° C. in a nitrogen (N₂) atmosphere for a period of time of from about 5 seconds to about 30 seconds.

11. A method of fabricating a semiconductor device, comprising:
forming a gate insulation layer on a semiconductor substrate;
forming a polysilicon layer on the gate isolation layer;
etching the gate insulation layer and the polysilicon layer to form a gate stack;
performing a first p-type impurity ion implantation process to form a shallow first impurity area in the semiconductor substrate;
forming a gate spacer layer on one side of the gate stack; and
performing a second p-type impurity ion implantation process using the gate spacer layer as a mask to form a deep second impurity area in the semiconductor substrate.

12. The method according to claim 11, wherein the performing a second p-type impurity ion implantation process comprises implanting p-type impurity ions at an implantation energy in the range of from about 10 keV to about 20 keV.

13. The method according to claim 11, wherein the performing a first p-type impurity ion implantation process comprises mixing and implanting boron (B) ions and BF₃ ions.

14. The method according to claim 11, wherein the performing a second p-type impurity ion implantation process comprises mixing and implanting B ions and BF₃ ions.

15. The method according to claim 13, wherein the performing a second p-type impurity ion implantation process comprises implanting B ions and BF₃ ions at an implantation energy in the range of from about 10 keV to about 20 keV.

16. The method according to claim 11, further comprising performing a diffusion process to diffuse the implanted impurity ions.

17. The method according to claim 16, wherein the diffusion process is a rapid thermal process performed at a temperature of from about 700° C. to about 1050° C. in a nitrogen (N₂) atmosphere for a period of time of from about 5 seconds to about 30 seconds.
